(19) United States
(12) Patent Application Publication
(10) Pub. No.: US 2003/0045118 A1
(43) Pub. Date: Mar. 6, 2003

(54) Method for controlling the critical dimension of the polysilicon gate by etching the hard mask

(75) Inventors: Yann-Pyng Wu, Miao-Li (TW); Yueh-Feng Ho, Hsin-Chu (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: UNITED MICROELECTRONICS CORP.

(21) Appl. No.: 09/945,653

(22) Filed: Sep. 5, 2001

(51) Int. Cl. H01L 21/302; H01L 21/461

(52) U.S. Cl. 438/733; 438/706

(57) ABSTRACT

First of all, a semiconductor substrate that has a gate dielectric layer thereon is provided. Then a polysilicon layer is formed on the gate dielectric layer. Next, a dielectric layer having a first thickness is formed on the polysilicon layer. Afterward, form and define a photoresist layer on the dielectric layer. The dielectric layer is then etched by way of using the photoresist layer as an etching mask and a mixing gas that comprises a C₂F₆ and a CH₂F₂ as an etchant until the polysilicon layer is over etched to consume a second thickness, so as to form a hard mask with a trapezoid profile, wherein the second thickness is about half of the first thickness. After removing the photoresist layer, the polysilicon layer is etched by way of using the hard mask as an etching mask to form a poly-gate.

### BACKGROUND OF THE INVENTION

1. Field of the Invention

The present invention relates generally to a method for forming the polysilicon gate, and more particularly to a process for controlling the critical dimension of the polysilicon gate by etching the hard mask.

2. Description of the Prior Art

As semiconductor devices, such as the Metal-Oxide-Semiconductor device, become highly integrated the area occupied by the device shrinks, as well as the design rule. With advances in the semiconductor technology, the dimensions of the integrated circuit (IC) devices have shrunk to the deep sub-micron range. When the semiconductor device continuously shrinks in the deep sub-micron region, some problems described below are incurred due to the scaling down process.

The evolution of integrated circuits has evolved such that scaling down the device geometry is required. In the deep sub-micron technology of semiconductors, it's necessary that the critical dimension of the poly-gate is smaller and smaller. To enlarge the litho-window, the thickness of the photoresist layer has to be decreased, thus, the hard mask is required in the poly-gate process integration. Traditionally, the oxide etch chamber is used to do etch the hard mask because of a higher selectivity between oxide and polysilicon, but usually it's a challenge to achieve a good critical dimension uniformity within a wafer. Furthermore, conventionally, the hard mask is etched by way of using the reactive gas that is a mixing gas with the carbon/fluorine ratio, such as C₂F₆, so as to control the etching profile during the etching process. Nevertheless, the uniformity of the polysilicon surface is poor due to the selectivity between oxide and polysilicon. After the hard mask is opened by way of using the mixing gas with the carbon/fluorine ratio, wherein the range of the polysilicon surface is about 200, that is, the surface difference of about 1700Å to 2000Å. The surface difference results in a difficulty with the follow-up etching process. Moreover, the polysilicon layer is over etched and lost until about half its thickness of the hard mask during the etching process of the hard mask, so that much of the polysilicon under the hard mask will be consumed, as shown in FIG. 1.

Further, the large range of the polysilicon makes the poly-gate etching more difficult. When the endpoint is polysilicon the hard mask cannot significantly or correctly be detected. When the polysilicon layer is etched by way of using the hard mask as an etching mask, the gate oxide layer is etched thoroughly into the substrate at the main endpoint. Therefore, regarding the etching process above, a large amount of the gate oxide layer will be lost while the polysilicon is removed. Controlling the thickness of the oxide layer is very important in the below deep sub-micron region. Especially, when the design rule is scaled down, the thickness of the oxide layer is reduced, resulting in a thickness more difficult to control or retain as the oxide layer requires. If the thickness of the oxide layer is too thin, it will affect the follow-up implanting process, and a possible shift in electricity will reduce the performance of the device. On the other hand, the hard mask has a vertical profile after etching process. Although the critical dimensions of the patterns in the photo-mask are the same, the critical dimension of the poly-gate in the isolating region on the wafer is always greater than the critical dimension of the poly-gate in the dense region on the wafer. Therefore, the conventional process for a poly-gate is a complex process. . The thickness of the oxide layer remains hard to control, and cannot be reworked, this in return increases cost.

In accordance with the above description, a new and improved method for the hard mask of the poly-gate is therefore necessary, so as to raise the yield and quality of the follow-up process.

### SUMMARY OF THE INVENTION

In accordance with the present invention, a method is provided that substantially overcomes the drawbacks of the above mentioned problems when forming the poly-gate by using existing conventional methods.

Accordingly, it is a main object of the present invention to provide an etching process for forming the hard mask of the poly-gate. This invention can use a mixing gas as an etchant to perform the etching process for forming the hard mask, so as to increase the etching selectivity between the hard mask and polysilicon layer. Furthermore, after over etching occurs, , this invention can obtain a better uniformity on the surface of the polysilicon layer. A significantly detected and correct endpoint between the polysilicon and the gate oxide layer reduces the consumption of the polysilicon layer. Therefore, this invention can reduce the costs of the conventional process and hence correspond to economic effect.

Another object of the present invention is to provide an etching process for forming the poly-gate. The present invention can perform an etching process by way of mixing gas with a CH₂F₂ and using a C₂F₆ as an etchant, so as to form the hard mask with a trapezoid profile. Moreover, this invention can also control the dimension of the hard mask trapezoid profile by the content of the CH₂F₂, so the critical dimension of the poly-gate is reduced in the isolating region and dense region can be free biased. Therefore, the present invention is appropriate for deep sub-micron technology when providing semiconductor devices.

In accordance with the present invention, a new method for forming the semiconductor devices is disclosed. First of all, a semiconductor substrate with a gate dielectric layer thereon is provided. Then a polysilicon layer is formed on the gate dielectric layer. Next, a dielectric layer with a first thickness is formed on the polysilicon layer. Afterward, a photoresist layer is formed and defined on the dielectric layer. The photoresist layer is used as an etching mask and a mixing gas that comprises a C₂F₆ and a CH₂F₂ as an etchant until the polysilicon layer is over etched to consume the second thickness, A hard mask with a trapezoid profile is the result, with the second thickness about half the first thickness. After removing the photoresist layer, the polysilicon layer is etched by way of using the hard mask as an etching mask to form a poly-gate.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows cross-sectional views illustrative of various stages for performing the etching process of the polysilicon layer in accordance with the conventional process;

FIG. 2A to FIG. 2D show cross-sectional views illustrative of various stages for forming the hard mask layer by way of using a new etchant in accordance with the first embodiment of the present invention; and

FIG. 3A to FIG. 3D show cross-sectional views illustrative of various stages for forming the hard mask and controlling the critical dimension of the poly-gate by way of using a new etchant in accordance with the second embodiment of the present invention.

### DESCRIPTION OF THE PREFERRED EMBODIMENT

These preferred embodiments of the present invention are now described in greater detail. Nevertheless, it should be recognized that the present invention can be practiced in a wide range of other embodiments besides those explicitly described, and the scope of the present invention is expressly not limited except as specified in the accompanying claims.

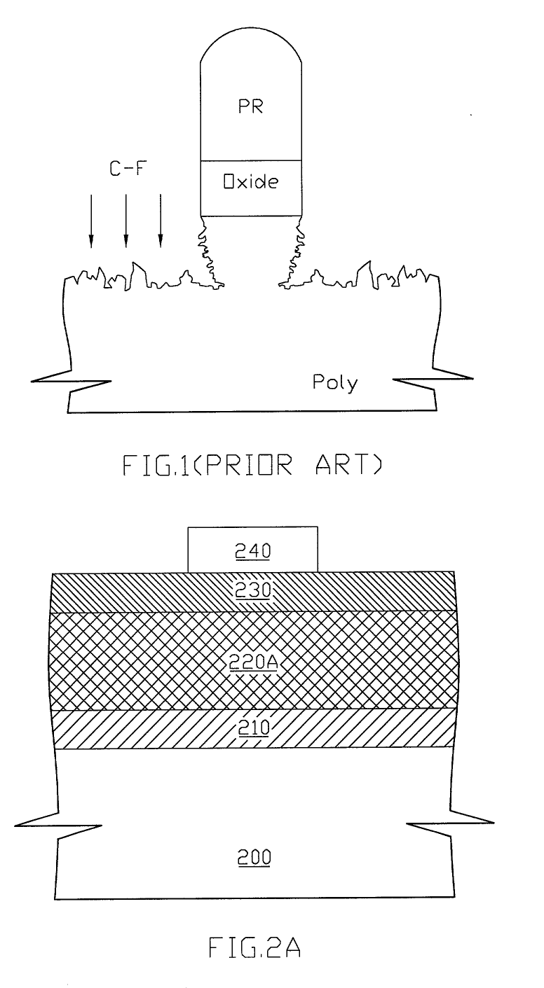

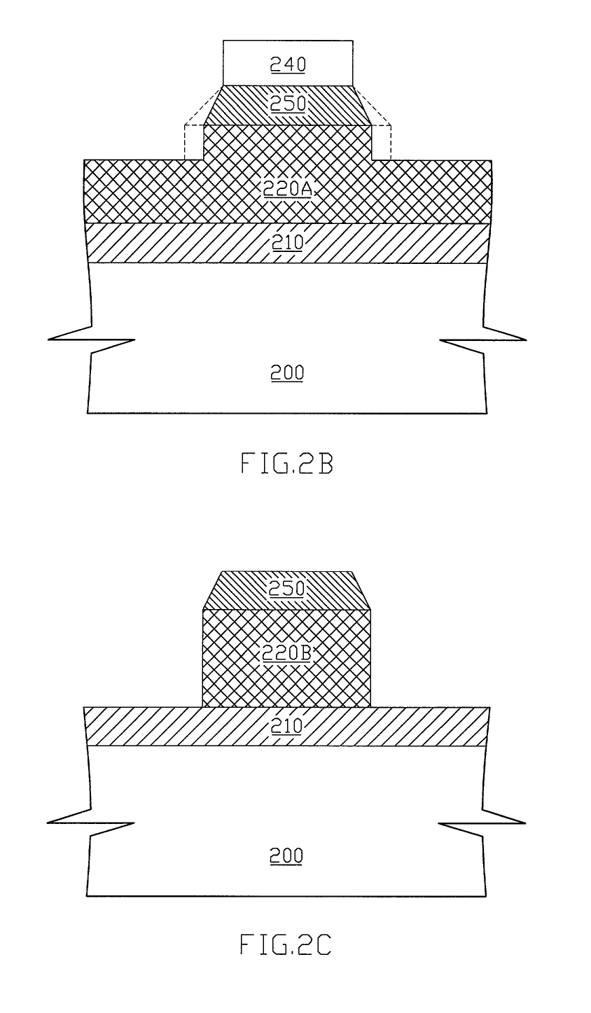

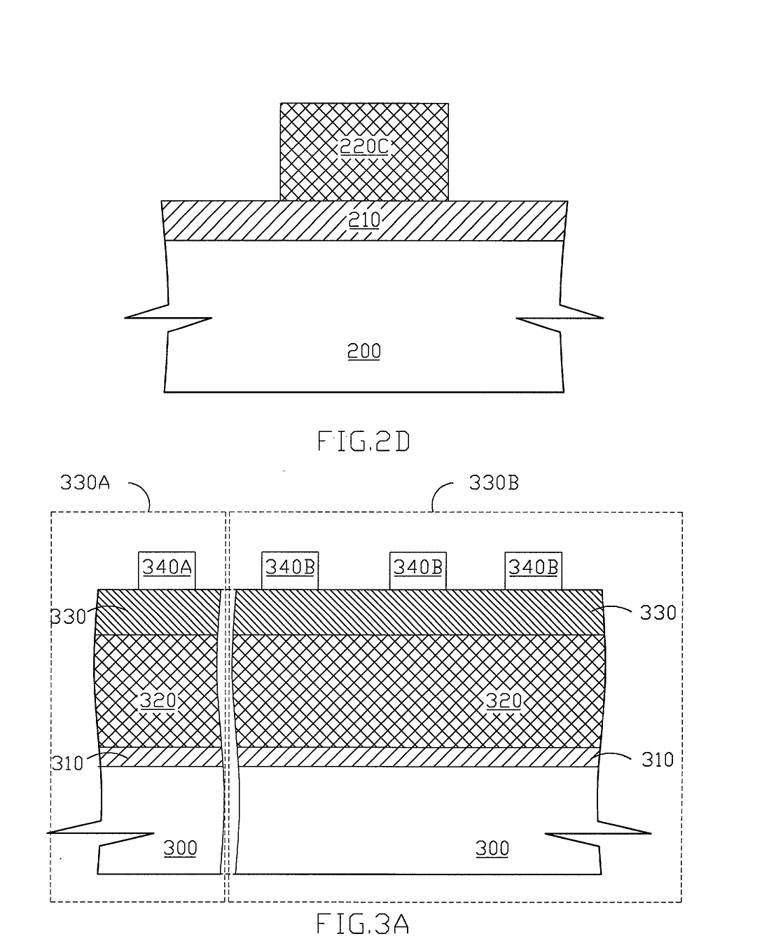

As illustrated in FIG. 2A to FIG. 2D, in the first embodiment of the present invention, a semiconductor substrate 200 that has a first dielectric layer 210 and a polysilicon layer 220A thereon is provided, wherein the first dielectric layer 210 comprises an oxide layer. Then a second dielectric layer 230 is formed on the polysilicon layer 220A, wherein the second dielectric layer 220 comprises an oxide layer. Next, a photoresist layer 240 is formed and defined on the second dielectric layer 230. An etching process is then performed by way of using the photoresist layer 240 as an etching mask and an etchant to etch the second dielectric layer 230 until the polysilicon layer 220A is over etched to a predetermined thickness, to form a hard mask 250 with a trapezoid profile. The profile of the trapezoid is determined by the etchant. The etchant comprises a reactive gas with a carbon/fluorine ratio, such as C₂F₆, and a reactive gas with hydrocarbon/fluorine ratio, such as CH₂F₆. The width of the trapezoid profile of the hard mask 250 is determined by the content of the reactive gas with hydrocarbon/fluorine ratio. If the content of the reactive gas with hydrocarbon/fluorine ratio is increased, the width of the trapezoid profile is increased. After removing the photoresist layer 240, the polysilicon layer 220A is etched by way of using the hard mask 250 as an etching mask to form a polysilicon region 220B. Finally, the hard mask 250 is stripped to form a poly-gate 220C.

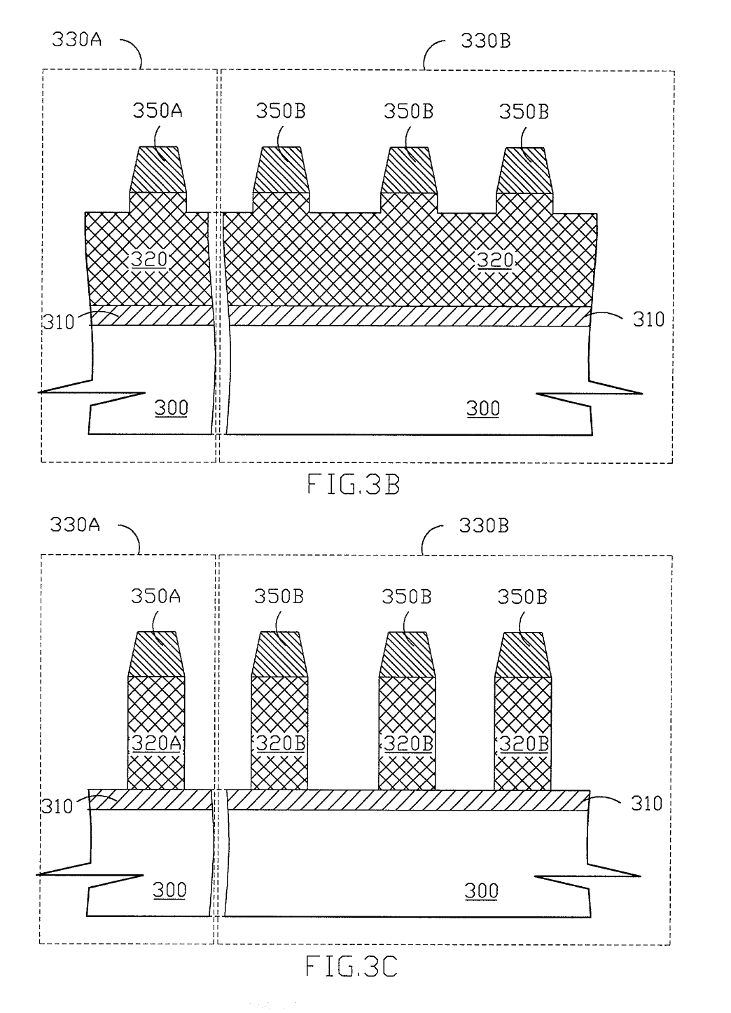

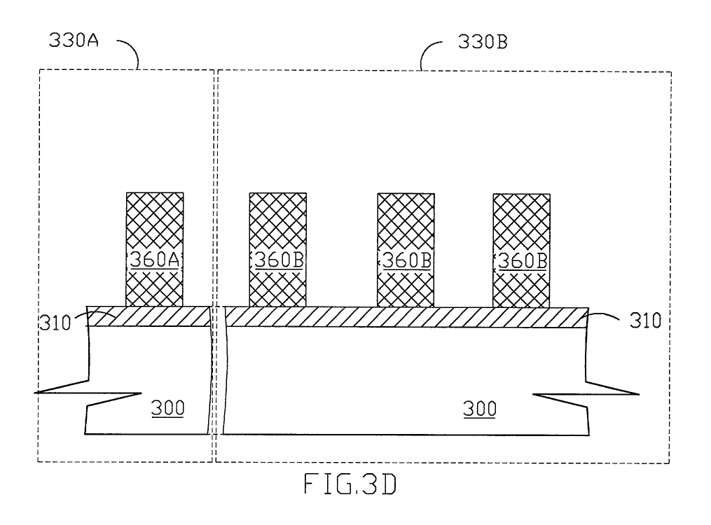

As illustrated in FIG. 3A and FIG. 3B, in the second embodiment of the present invention, a semiconductor substrate 300 that has a gate oxide layer 310 thereon is provided. Then a polysilicon layer 320 is formed on the gate oxide layer 310. Next, an oxide layer 330 with a first thickness is formed on the polysilicon layer 320. Afterward, form and define a plurality of first photoresist layers 340A and a plurality of second photoresist layers 340B on the oxide layer 330. Wherein the plurality of first photoresist layers 340A are located on the isolating region 300A and the plurality of the second photoresist layers 340B are located on the dense region 300B. An etching process is then performed by way of using the plurality of first photoresist layers 340A and the plurality of the second photoresist layers 340B. A plurality of etching masks and a mixing gas as an etchant is used to etch the oxide layer 330 until the polysilicon layer 320 is over etched to consume a second thickness of the polysilicon layer 320. A plurality of the first hard masks 350A with the second hard masks 350B with matching trapezoid profiles have been formed. The mixing gas comprises a reactive gas with a C₂F₆ and a reactive gas with a CH₂F₆with the widths of the trapezoid profiles 350A and 350B being determined by the content amounts of the reactive gas and the CH₂F₆. If the content of the reactive gas with the CH₂F₆ is increased, the widths of the trapezoid profiles of the plurality of first hard masks 350A and the plurality of second hard masks 350B are increased, so as to control the critical dimension of the poly-gate. Furthermore, the plurality of first hard masks 350A are located on the isolating region 300A and the plurality of second hard masks 350B are located on the dense region 300B, and the second thickness is half the first thickness. On the other hand, the plurality of first hard masks 350A and the plurality of second hard masks 350B can have trapezoid profiles with different bias by using additional photolithography process'.

Referring to FIG. 3C and FIG. 3D, in this embodiment, after removing the plurality of the first photoresist layers 340A and the plurality of the second photoresist layers 340B, the polysilicon layer 320 is etched by way of using the plurality of the first hard masks 350A and the plurality of the second hard masks 350B as a plurality of the etching masks to form a plurality of the first polysilicon region 320A and a plurality of the second polysilicon region 320B. The plurality of first polysilicon region 320A are located on the isolating region 300A and the plurality of second polysilicon region 320B are located on the dense region 300B. Finally, the plurality of first hard masks 350A and the plurality of second hard masks 350B are stripped to form a plurality of first poly-gates 360A that are located on the isolating region 300A and a plurality of second poly-gates 360B that are located on the dense region 300B.

In these embodiments of the present invention, as discussed above, this invention can use a mixing gas as an etchant to perform the etching process for forming the hard mask, so as to increase the etching selectivity between the hard mask and polysilicon layer. The etching selectivity in the conventional process is about less than 1.5, but the etching selectivity in this invention is about greater than 5. Furthermore, after over etching of the polysilicon layer, this invention can obtain a better uniformity of the surface of the polysilicon. The detection of the correct endpoint between the polysilicon and the gate oxide layer significantly reduces the consumption of the polysilicon layer. In the conventional process the surface range is about great than 200, but the surface range in this invention is about less than 50. Hence, this invention can reduce the costs of the conventional process and hence correspond to economic effect. Moreover, the present invention can perform an etching process by way of using a mixing gas with a CH₂F₂ and a C₂F₆ as an etchant, so as to form the hard mask with the trapezoid profile. In addition, this invention also can control the dimension of the trapezoid profile of the hard mask by the content of the CH₂F₂, and as a result the critical dimension of the poly-gate in the isolating region and dense region can be free biased. Accordantly, the control window of the critical dimension bias becomes wider and wider. Therefore, the present invention is appropriate for deep sub-micron technology in providing semiconductor devices.

Of course, it is possible to apply the present invention to the etching process for forming the hard mask of the polysilicon layer, and it is also possible for the present invention to be applied to any etching process in the production of a semiconductor device. Furthermore, at the present time, the content of CH₂F₂ of the mixing gas in this invention can be applied to the etching process of the polysilicon layer concerning control the critical dimension of the poly-gate. The method of the present invention is the best process for forming the poly-gate compatible process for deep sub-micron process.

Obviously, many modifications and variations of the present invention are possible in light of the above teachings. It is to be understood that within the scope of the appended claims, the present invention may be practiced other than as specifically described herein.

Although the specific embodiments have been illustrated and described, it will be obvious to those skilled in the art that various modifications may be made without departing from what is intended to be limited solely by the appended claims.

What is claimed is:

1. A method for etching a hard mask, the method comprising:
providing a semiconductor substrate having a polysilicon layer thereon;
forming a dielectric layer on said polysilicon layer;
forming a photoresist layer on said dielectric layer;
providing a mixing gas with a hydrocarbon/fluorine ratio as an etchant; and
etching said dielectric layer by way of using said photoresist layer as an etching mask and said etchant to form a hard mask with a trapezoid profile.

2. The method according to claim 1, wherein said dielectric layer comprises an oxide layer.

3. The method according to claim 1, wherein said mixing gas with said hydrocarbon/fluorine ratio comprises a CH₂F₂.

4. The method according to claim 1, wherein the width of said trapezoid profile of said hard mask is determined by way of using the content of said mixing gas with said hydrocarbon/fluorine ratio.

5. A method for etching a polysilicon layer, the method comprising:
providing a semiconductor substrate having a first dielectric layer thereon;
forming a polysilicon layer on said first dielectric layer;
forming a second dielectric layer on said polysilicon layer;
forming a photoresist layer on said second dielectric layer;
providing a mixing gas with a carbon/fluorine ratio and a hydrocarbon/fluorine ratio as an etchant;
etching said second dielectric layer by way of using said photoresist layer as an etching mask and said etchant and over etching said polysilicon layer until a predetermined thickness, so as to form a hard mask with a trapezoid profile;
tripping said photoresist layer; and
etching said polysilicon layer by way of using said hard mask as an etching mask to form a polysilicon region on said first dielectric layer.

6. The method according to claim 5, wherein said first dielectric layer comprises an oxide layer.

7. The method according to claim 5, wherein said second dielectric layer comprises an oxide layer.

8. The method according to claim 5, wherein said mixing gas with said carbon/fluorine ratio comprises a C₂F₆.

9. The method according to claim 5, wherein said mixing gas with said hydrocarbon/fluorine ratio comprises a CH₂F₂.

10. The method according to claim 5, wherein the width of said trapezoid profile of said hard mask is determined by way of using the content of said mixing gas with said hydrocarbon/fluorine ratio.

11. A method for controlling the width of a plurality of poly-gates, the method comprising:
providing a semiconductor substrate having a gate oxide layer thereon;
forming a polysilicon layer on said gate oxide layer;
forming a dielectric layer with a first thickness on said polysilicon layer;
forming a plurality of photoresist layers on said dielectric layer;
providing a mixing gas with a CH₂F₂ as an etchant;
etching said dielectric layer by way of using said plurality of photoresist layers as a plurality of etching masks and said etchant and over etching said polysilicon layer until removing a second thickness of said polysilicon layer, so as to form a plurality of hard masks with a trapezoid profile, wherein the critical dimension of said plurality of poly-gate are controlled by way of the width of said trapezoid profile of said plurality of hard masks;
tripping said plurality of photoresist layers;
etching said polysilicon layer by way of using said plurality of hard masks as a plurality of etching masks to form a plurality of polysilicon region on said gate oxide layer; and
removing said plurality of hard masks to form said plurality of poly-gates.

12. The method according to claim 11, wherein said dielectric layer comprises an oxide layer.

13. The method according to claim 11, wherein said second thickness is about a half of said first thickness.

14. The method according to claim 11, wherein the width of said trapezoid profile of said plurality of hard masks are determined by way of using the content of said mixing gas with said CH₂F₂.

15. A method for controlling the width of a plurality of poly-gates, the method comprising:
providing a semiconductor substrate having a gate oxide layer thereon;
forming a polysilicon layer on said gate oxide layer;
forming an oxide layer with a first thickness on said polysilicon layer;
forming a plurality of first photoresist layers and a plurality of second photoresist layers on said oxide layer, wherein said plurality of first photoresist layers are located on an isolating region and said plurality of second photoresist layers are located on a dense region;
providing a mixing gas with a CH₂F₂ and a C₂F₆ as an etchant;
etching said oxide layer by way of using said plurality of first photoresist layers and said plurality of second photoresist layers as a plurality of etching masks and said etchant and over etching said polysilicon layer until removing a second thickness of said polysilicon layer, so as to form a plurality of first hard masks with a trapezoid profile on said isolating region and a plurality of second hard masks with a trapezoid profile on said dense region, wherein the widths of said trapezoid profile of said plurality of first hard masks and said plurality of second hard masks are determined by way of using the content of said CH₂F₂ of said mixing gas to control the critical dimension of said plurality of said poly-gates;
tripping said plurality of first photoresist layers and said plurality of second photoresist layers;
etching said polysilicon layer by way of using said plurality of first hard masks and said plurality of second hard masks as a plurality of etching masks to form a plurality of first polysilicon regions on said isolating region and a plurality of second polysilicon regions on said dense region; and
removing said plurality of first hard masks and said plurality of second hard masks to form said plurality of first poly-gates on said isolating region and said plurality of second poly-gates on said isolating region.

16. The method according to claim 15, wherein said second thickness is about a half of said first thickness.
